(19) United States
(12) Patent Application Publication
(10) Pub. No.: US 2012/0152753 A1
(43) Pub. Date: Jun. 21, 2012

(54) METHOD OF MANUFACTURING PRINTED CIRCUIT BOARD

(75) Inventors: Suk Won LEE, Gyunggi-do (KR); Tae Eun CHANG, Gyunggi-do (KR); Ho Sik PARK, Gyunggi-do (KR); Keung Jin SOHN, Gyunggi-do (KR)

(73) Assignee: SAMSUNG ELECTRO-MECHANICS CO., LTD., Gyunggi-do (KR)

(21) Appl. No.: 13/045,941

(22) Filed: Mar. 11, 2011

(30) Foreign Application Priority Data
Dec. 21, 2010 (KR) 10-2010-0131347

(51) Int. Cl. C25D 5/02; H05K 3/00

(52) U.S. Cl. 205/125

(57) ABSTRACT

Disclosed herein is a method of manufacturing a printed circuit board that simultaneously forms a via and an embedding land and thus improves the matching value of the via and the embedding land to secure interlayer conduction reliability, and further simultaneously forms the via and the embedding land to reduce manufacturing costs. In addition, the embedding land is formed to be embedded in the second insulating layer to implement high-density/high-integration of the printed circuit board and a via is formed in less time as compared to a method of forming a via hole using laser to reduce a process time.

### CROSS REFERENCE TO RELATED APPLICATION

This application claims the benefit of Korean Patent Application No. 10-2010-0131347, filed on Dec. 21, 2010, entitled “Method Of Manufacturing Printed Circuit Board”, which is hereby incorporated by reference in its entirety into this application.

### BACKGROUND OF THE INVENTION

1. Technical Field

The present invention relates to a method of manufacturing a printed circuit board.

2. Description of the Related Art

With the recent development of the electronic industry, a demand for high performance and miniaturization of electronic components has increased. Therefore, research and development for implementing a high density circuit pattern on a printed circuit board on which the electronic components are mounted have been conducted.

A method of manufacturing a printed circuit board according to the prior art will be described with reference to FIGS. 1 to 3.

First, as shown in FIG. 1, a base substrate 10 is prepared, the base substrate 10 including a core layer 13 formed with an inner via 11 and an inner circuit layer 15 formed on one surface or both surfaces of the core layer 13. Thereafter, an insulating layer 20 is stacked on both surfaces of the base substrate 10 and a via hole 25 is machined using laser.

Then, as shown in FIG. 2, a seed layer 27 is formed at an inner wall of the via hole 25 and an exposed surface of the insulating layer 20, and a plating resist 30 is applied to a surface of the seed layer 27. Then, the plating resist 30 is patterned to open a region in which a circuit pattern 41 (in FIG. 3) or a land 43 (in FIG. 3) is to be formed.

Then, as shown in FIG. 3, the via hole 25 (in FIG. 2) is plated to form a via 45, and an outer circuit layer 40 is formed on the seed layer 27 exposed from the plating resist 30 (in FIG. 2). The outer circuit layer 40 is formed by electroplating using the seed layer 27 as a lead line, and the plating resist 30 and the seed layer 27 exposed from the outer circuit layer 40 are removed after the outer circuit layer 40 is formed.

The method of manufacturing a printed circuit board according to the prior art has the following problems.

First, a process of machining the via hole 25 in the insulating layer 20 and process of applying and patterning the plating resist 30 so as to open the region on which the land 43 is to be formed are performed, respectively. In this case, the matching value between the via 45 and the land 43 is degraded due to the machining errors of machining equipment for forming the via hole 25 and the machining errors of exposure equipment of the plating resist 30 for forming the circuit patter 41 and the land 43 and as a result, interlayer conduction reliability is degraded.

In addition, the land 43 of the printed circuit board according to the prior art is generally formed to be protruded from the insulating layer 20; however, an area of the land 43 should be formed to be larger than an upper area of the via hole 25 so as to secure the interlayer conduction reliability. A size of the land 43 is determined according to machinability of the via hole and the matching ability of the circuit. However, the size of the land 43 generally occupies a considerable area (seven times or more of the upper area of the via hole) of the printed circuit board and thus, it becomes an obstacle to implement a high-integration/high-density printed circuit board.

### SUMMARY OF THE INVENTION

The present invention has been made in an effort to provide a method of manufacturing a printed circuit board that simultaneously forms a via and a land and thus improves the matching value of the via and the land to secure interlayer conduction reliability, while implementing a high-integration/high-density printed circuit board.

According to a preferred embodiment of the present invention, there is provided a method of manufacturing a printed circuit board, including: (A) providing a base substrate including a first insulating layer, and an inner circuit layer formed on both surfaces of the first insulating layer and including a circuit pattern and a pad part; (B) applying a first plating resist to both surfaces of the base substrate and patterning the first plating resist to form an opening so that the pad part is exposed; (C) forming a metal post including a via formed in the opening through a plating process and a protruding part extending from the via and protruding from the exposed surface of the first plating resist and having a diameter larger than that of the via; (D) after removing the first plating resist, stacking a second insulating layer on both surfaces of the base substrate so that the metal post is embedded; and (E) forming an embedding land by polishing the second insulating layer and the protruding part and exposing a traverse surface of the protruding part embedded in the second insulating layer.

The method may further include (F) forming an outer circuit layer on the second insulating layer.

The base substrate may further include an inner via penetrating through the first insulating layer to electrically connect the pad part.

The protruding part at step (C) may have a thickness of 30 μm to 60 μm protruding from the first plating resist.

The embedding land at step (E) may be formed by polishing the protruding part to have a thickness of 10 μm to 30 μm.

Step (A) may include: (A1) forming a through hole in the first insulating layer; (A2) forming a first seed layer on the first insulating layer including the through hole; and (A3) forming the inner circuit layer in the first insulating layer through an electroplating process using the first seed layer as a lead line and forming an inner via by plating an inside of the through hole.

Step (D) may further include, after removing the first plating resist, removing the first seed layer exposed from the inner circuit layer.

Step (F) may include: (F1) forming a second seed layer on the second insulating layer; (F2) applying a second plating resist to the second seed layer and patterning the second plating resist so that the second seed layer formed on the embedding land is exposed; (F3) forming the outer circuit layer on the second seed layer exposed from the second plating resist through an electroplating process; and (F4) removing the second plating resist and removing the second seed layer exposed from the outer circuit layer.

The second seed layer may be made of a metal different from the metal post

The second seed layer may be made of nickel (Ni), gold (Au), silver (Ag), zinc (Zn), palladium, ruthenium (Ru), rhodium (Rh), a lead (Pb)-tin (Sn) based soldering alloy, and a nickel (Ni)-gold (Au) alloy.

The inner circuit layer may be made of copper.

The metal post may be made of copper.

The outer circuit layer may be made of copper.

### BRIEF DESCRIPTION OF THE DRAWINGS

FIGS. 1 to 3 are cross-sectional views showing a method of manufacturing a printed circuit board according to the prior art in a process sequence; and

FIGS. 4 to 16 are cross-sectional views showing a method of manufacturing a printed circuit board according to the present invention in a process sequence.

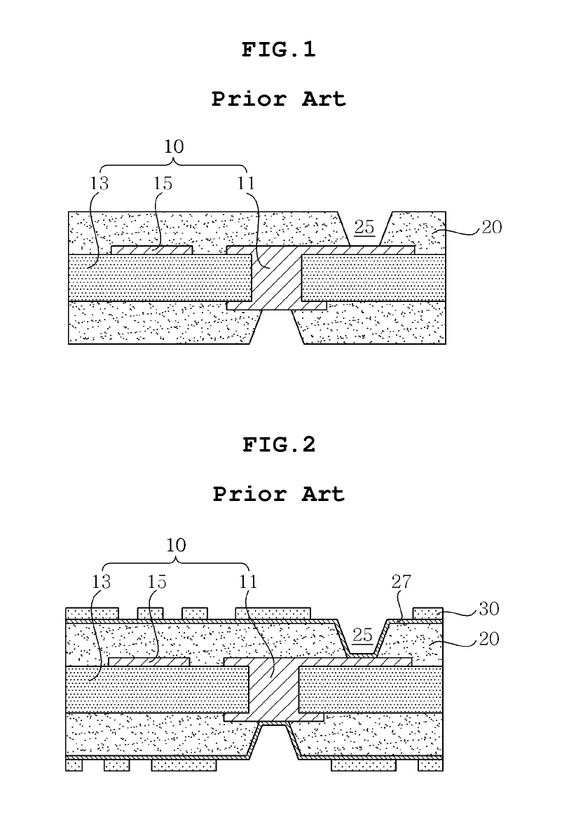

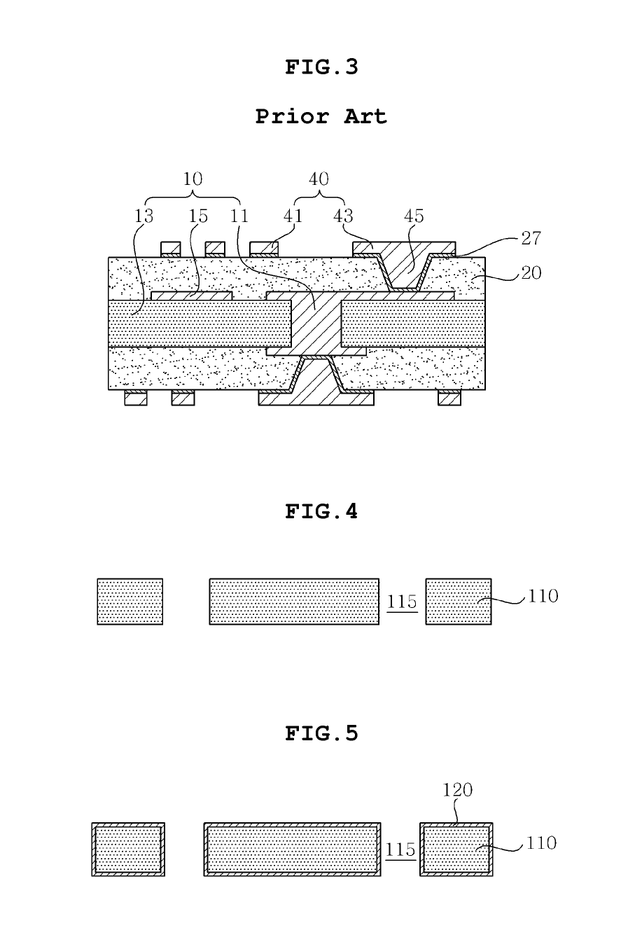

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

FIGS. 4 to 16 are process cross-sectional views showing a method of manufacturing a printed circuit board according to the present invention. Hereinafter, a method of manufacturing a printed circuit board according to a preferred embodiment of the present invention will be described with reference to FIGS. 4 to 16.

First, as shown in FIG. 4, a through hole 115 is machined in a first insulating layer 110 by machine drilling such as a CNC drilling or CO2/YAG laser. The first insulating layer 110 may be made of an insulating material that is generally used in a printed circuit board, for example, a composite polymer resin such as prepreg (PPG). In addition, the first insulating layer 110 may include an epoxy-based resin such as FR-4, BT or the like or Ajinomoto build-up film (ABF) or the like, but the material thereof is not particularly limited thereto.

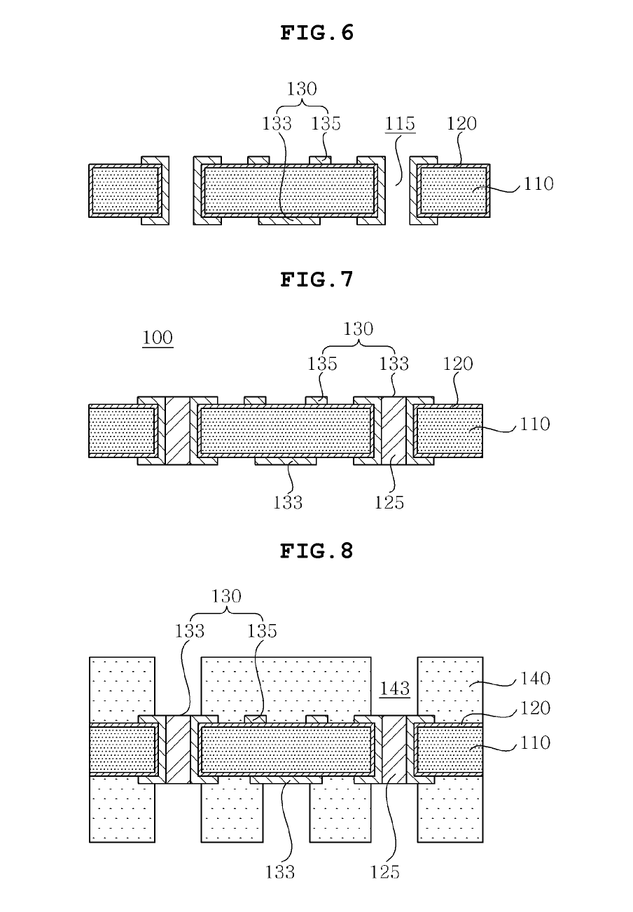

Then, as shown in FIG. 5, a first seed layer 120 is formed on the first insulating layer 110 including the through hole 115. In this case, the first seed layer 120 serves as a lead line for an electroplating process, wherein the first seed layer 120 may be preferably formed to have a predetermined thickness or more (for example, 1 μm) so as to form an inner circuit layer 130 (in FIG. 6) by an electroplating process. The first seed layer 120 may be formed by an electroless plating method or a sputtering method. The electroless plating method is a process performed through a degreasing process, a soft etching process, a preliminary catalyst treatment process, a catalyst treatment process, an activation process, an electroless plating process, and an oxidation prevention treatment process. Meanwhile, the sputtering method is a process of forming an electroless plating layer on an insulating layer by colliding ion particles of gas generated by plasma or the like with a thin film material.

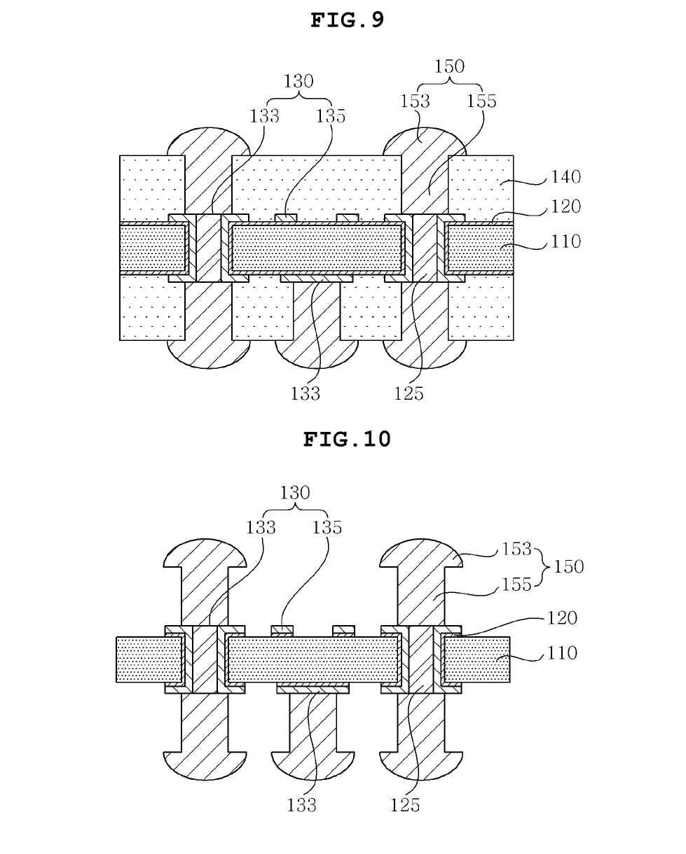

Then, as shown in FIG. 6, an inner circuit layer 130 is formed on the first insulating layer 110 by an electroplating process using the first seed layer 120 as a lead line. The inner circuit layer 130 includes a circuit pattern 135 and a pad part 133. A circuit layer may be generally formed on an insulating layer by a subtractive method, an additive method, a semi-additive method, a modified semi-additive method and the like. However, in the present embodiment of the present invention, the first seed layer 120 is used again as the lead line for performing electroplating in the process for forming a metal post 150 (see FIG. 9), such that the inner circuit layer 130 is preferably formed using the semi-additive method. In particular, the first seed layer 120 is used again in the operation of forming the metal post 150, such that the first seed layer 120 remains on the first insulating layer 110 even after the inner circuit layer 130 is formed and is thus finally removed after the metal post 150 is formed. In this case, the inner circuit layer 130 may be made of an electrical conductive metal, for example, gold, silver, copper, nickel, or the like, and the material thereof is not particularly limited; however, it may be preferably made of copper, which is generally used.

Then, as shown in FIG. 7, an inner via 125 is formed by plating an inside of the through hole 115 (in FIG. 6). A base substrate 100 including the first insulating layer 110, the first seed layer 120, the inner circuit layer 130, and the inner via 125 is provided.

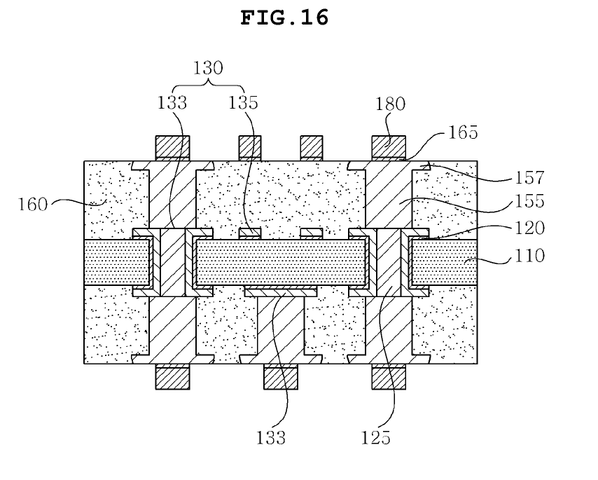

Then, as shown in FIG. 8, a first plating resist 140 is applied to both surfaces of the base substrate 100 (in FIG. 7) and the first plating resist 140 is patterned to form an opening 143 so that the pad part 133 is exposed. In this case, as a photosensitive material used in the first plating resist 140, a dry film or a liquid-phase photosensitive material may be used, wherein the photosensitive material may be preferably formed to have a thickness of 30 μm or more so as to secure an insulating distance between the inner circuit layer 130 and an outer circuit layer 60 (in FIG. 16). More specifically, the first plating resist 140 is applied to both surfaces of the base substrate 100 and ultraviolet rays are irradiated to the first plating resist 140 in a state being blocked using a mask. Thereafter, when the first plating resist 140 is applied with a developer, cured portions thereof are maintained as they are but non-cured portions thereof are removed due to the selective irradiation of the ultraviolet rays, such that the first plating resist 140 having the opening 143 is formed.

Then, as shown in FIG. 9, a via 155 is formed in the opening 143 (in FIG. 8) and a protruding part 153 extending from the via 155 and protruding from the exposed surface of the first plating resist 140 and having a diameter larger than that of the via 155, such that a metal post 150 including the via 155 and the protruding part 153 is formed. In this case, the via 155 and the protruding part 153 are simultaneously formed through a plating process. In other words, the electroplating is performed using, as the lead line, the first seed layer 120 remaining in the first insulating layer 110 after the inner circuit layer 130 is formed, thereby forming the via 155. Then, the amount of plating is controlled to form the protruding part 153 protruding from the via 155 to cover the first plating resist 140 around the opening 143. In this case, the protruding part 153 has a thickness of 30 μm to 60 μm protruding from the exposed surface of the first plating resist 140 and a predetermined portion of the thickness thereof is to be polished in a subsequent process to be configured as a embedded land 157. The protruding part 153 may have a hemisphere shape in which flat surfaces thereof contact the first plating resist 140. In this case, the diameter of the protruding part 153 is larger than that of the via 155 but should be in a range so as not to contact another protruding part 153 adjacent thereto. In this case, the material of the metal post 150 is not particularly limited but may be preferably made of copper plating, which is generally used.

Then, as shown in FIG. 10, the first plating resist 140 (in FIG. 9) and the first seed layer 120 are removed. The first plating resist 140 may be removed using a stripper such as NaOH, KOH, or the like, and the first seed layer 120 may be removed by flash etching or soft etching, the first seed layer 120 being exposed from the inner circuit layer 130 after the first plating resist 140 is removed.

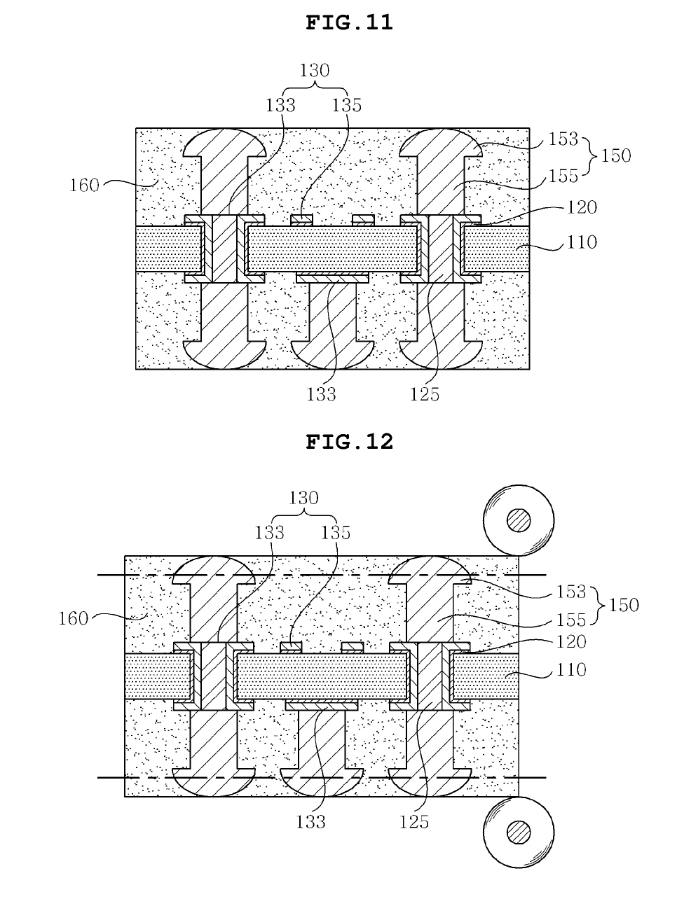

Then, as shown in FIG. 11, a second insulating layer 160 is stacked on both surfaces of the base substrate 100 (in FIG. 7) so that the metal post 150 is embedded. In other words, the semi-cured second insulating layer 160 is prepared so that the metal post 150 may penetrate therethrough and then is stacked on the base substrate 100 to be cured. The second insulating layer 160 may have a thickness sufficient enough for the metal post 150 to be completely embedded; however, a thickness of the second insulating layer 160 may be preferably controlled so that the exposed surface of the second insulating layer 160 is present on the same plane as the protruding part 153 of the metal post 150. The second insulating layer 160 may be made of an insulating material, which is generally used in a printed circuit board. The kind of material thereof is the same as that of the first insulating layer 110 and thus, an overlapping explanation thereof will be omitted.

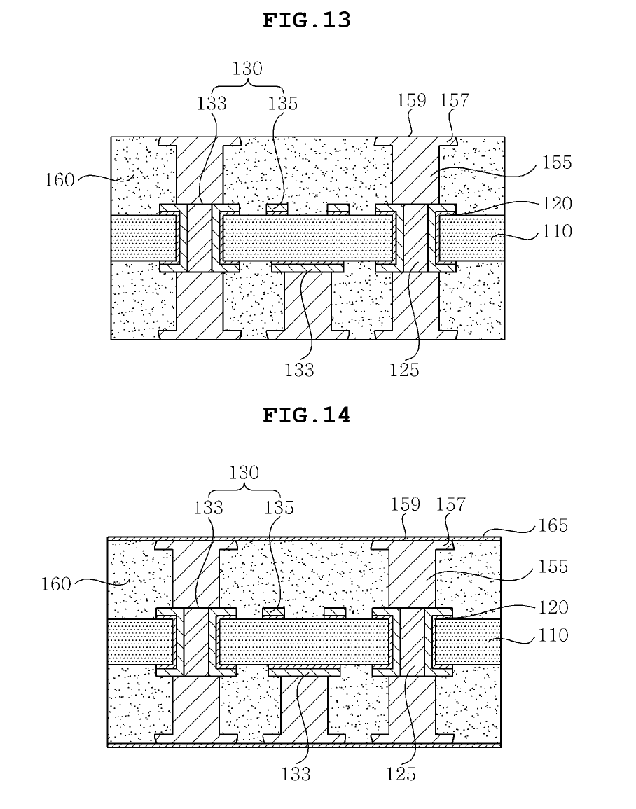

Then, as shown in FIGS. 12 and 13, the second insulating layer 160 and the protruding part 153 are polished to expose a traverse surface 159 of the protruding part 153 embedded in the second insulating layer 160, thereby forming the embedding land 157. In this case, the second insulating layer 160 and the protruding part 153 may be mechanically polished using a ceramic buff, a belt sander, or the like. In the present operation, the two second insulating layers 160 stacked on the base substrate 100 may be polished in sequence and the exposed surfaces of the two second insulating layers 160 may also be simultaneously polished (FIG. 12). The protruding part 153 may be preferably polished to have a thickness of 10 μm to 30 μm and the traverse surface 159 of the protruding part 153 may be exposed by the polishing process in the present operation. When a portion of the second insulating layer 160 and a portion of the protruding part 153 are collectively removed by polishing, the traverse surface 159 of the protruding part 153 is exposed from the surface of the second insulating layer 160 and the protruding part 153 not removed is embedded in the second insulating layer 160, thereby forming the embedding land 157 (FIG. 13).

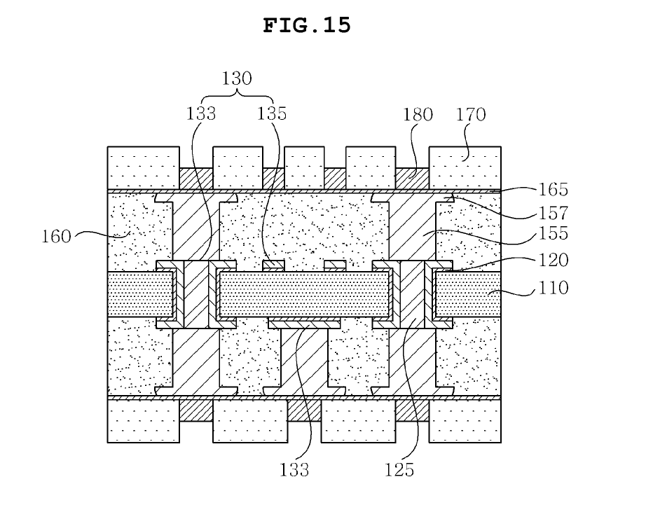

Then, as shown in FIG. 14, a second seed layer 165 is formed on the second insulating layer 160 so as to form an outer circuit layer 180 (in FIG. 16). The second seed layer 165 may be formed by an electroless plating method or a sputtering method. The detailed method thereof is the same as that of forming the first seed layer 120 and thus, an overlapping explanation thereof will be omitted. However, the second seed layer 165 is made of a metal different from the metal post 150 (in FIG. 12). The reason is to prevent not only the second seed layer 165 but also the embedding land 157 of the metal post 150 from being etched during the etching of the second seed layer 165 exposed from the outer circuit layer 180, when the second seed layer 165 is made of the same metal as the metal post 150. As the material of the second seed layer 165, at least any one of nickel (Ni), gold (Au), silver (Ag), zinc (An), palladium, ruthenium (Ru), rhodium (Rh), a lead (Pb)-tin (Sn) based soldering alloy, and a nickel (Ni)-gold (Au) alloy may be used.

Then, as shown in FIG. 15, a second plating resist 170 is applied to the second seed layer 165 and the second plating resist 170 is patterned so that portions of the second seed layer 165 corresponding to the outer circuit layer 180 are exposed. The method of patterning the second plating resist 170 is the same as that of patterning the first plating resist 140.

Then, as shown in FIG. 16, after the outer circuit layer 180 is formed by performing electroplating on the second seed layer 165 exposed from the second plating resist 170, the second plating resist 170 and the second seed layer 165 exposed from the outer circuit layer 180 are removed. In this case, the second seed layer 165 serves as a lead line for performing electroplating and is removed by soft etching or flash etching after the outer circuit layer 180 is formed. In this case, the outer circuit layer 180 may be made of an electrical conductive metal, for example, gold, silver, copper, nickel, or the like, and the material thereof is not particularly limited; however, it may be preferably made of copper, which is generally used.

Meanwhile, a method of implementing a multi-layer printed circuit board by repeatedly performing a series of processes including: applying and patterning a third plating resist (not shown) to the second seed layer 165 without directly removing the second seed layer 165, forming the metal post 150 by using again the second seed layer 165 as a lead line, removing the third plating resist and the second seed layer 165, forming a third insulating layer (not shown), and forming the embedding land 157 by polishing, may also be included in the scope of the present invention.

The method of manufacturing a printed circuit board according to the present invention simultaneously forms the via and the land and improves matching values of the via and the land, thereby making it possible to improve interlayer conduction reliability.

In addition, the land is formed to be embedded in the insulating layer, thereby making it possible to implement high density/high integration of the printed circuit board.

In addition, the via may be formed in less time as compared to a method of forming a via hole using laser, thereby making it possible to reduce a process time and the via and the land are simultaneously formed, thereby making it possible to reduce manufacturing costs of the printed circuit board.

Although the preferred embodiments of the present invention have been disclosed for to illustrative purposes, they are for specifically explaining the present invention and thus the method of manufacturing a printed circuit board according to the present invention is not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A method of manufacturing a printed circuit board, comprising:
(A) providing a base substrate including a first insulating layer, and an inner circuit layer formed on both surfaces of the first insulating layer and including a circuit pattern and a pad part;
(B) applying a first plating resist to both surfaces of the base substrate and patterning the first plating resist to form an opening so that the pad part is exposed;
(C) forming a metal post including a via formed in the opening through a plating process and a protruding part extending from the via and protruding from the exposed surface of the first plating resist and having a diameter larger than that of the via;
(D) after removing the first plating resist, stacking a second insulating layer on both surfaces of the base substrate so that the metal post is embedded; and
(E) forming an embedding land by polishing the second insulating layer and the protruding part and exposing a traverse surface of the protruding part embedded in the second insulating layer.

2. The method of manufacturing a printed circuit board as set forth in claim 1, further comprising (F) forming an outer circuit layer on the second insulating layer.

3. The method of manufacturing a printed circuit board as set forth in claim 1, wherein the base substrate further includes an inner via penetrating through the first insulating layer to electrically connect the pad part.

4. The method of manufacturing a printed circuit board as set forth in claim 1, wherein the protruding part at step (C) has a thickness of 30 μm to 60 μm protruding from the first plating resist.

5. The method of manufacturing a printed circuit board as set forth in claim 1, wherein the embedding land at step (E) is formed by polishing the protruding part to have a thickness of 10 μm to 30 μm.

6. The method of manufacturing a printed circuit board as set forth in claim 1, wherein step (A) includes:
(A1) forming a through hole in the first insulating layer;
(A2) forming a first seed layer on the first insulating layer including the through hole; and
(A3) forming the inner circuit layer in the first insulating layer through an electroplating process using the first seed layer as a lead line and forming an inner via by plating an inside of the through hole.

7. The method of manufacturing a printed circuit board as set forth in claim 6, wherein step (D) further includes, after removing the first plating resist, removing the first seed layer exposed from the inner circuit layer.

8. The method of manufacturing a printed circuit board as set forth in claim 2, wherein step (F) includes:
(F1) forming a second seed layer on the second insulating layer;
(F2) applying a second plating resist to the second seed layer and patterning the second plating resist so that the second seed layer formed on the embedding land is exposed;
(F3) forming the outer circuit layer on the second seed layer exposed from the second plating resist through an electroplating process; and
(F4) removing the second plating resist and removing the second seed layer exposed from the outer circuit layer.

9. The method of manufacturing a printed circuit board as set forth in claim 8, wherein the second seed layer is made of a metal different from the metal post.

10. The method of manufacturing a printed circuit board as set forth in claim 8, wherein the second seed layer is made of nickel (Ni), gold (Au), silver (Ag), zinc (Zn), palladium, ruthenium (Ru), rhodium (Rh), a lead (Pb)-tin (Sn) based soldering alloy, and an nickel (Ni)-gold (Au) alloy.

11. The method of manufacturing a printed circuit board as set forth in claim 1, wherein the inner circuit layer is made of copper.

12. The method of manufacturing a printed circuit board as set forth in claim 1, wherein the metal post is made of copper.

13. The method of manufacturing a printed circuit board as set forth in claim 2, wherein the outer circuit layer is made of copper.
